(19) United States
(12) Patent Application Publication
(10) Pub. No.: US 2026/0293712 A1
(43) Pub. Date: Sep. 24, 2026

(54) PACKAGE FOR SIDE-BY-SIDE DIES WITH DEVICE-TO-DEVICE BRIDGE AND SUBSTRATE INTERCONNECTIONS

(71) Applicant: QUALCOMM Incorporated, San Diego, CA (US)

(72) Inventors: Joan Rey Villarba BUOT, Escondido, CA (US); Aniket PATIL, San Diego, CA (US); Manuel ALDRETE, Encinitas, CA (US)

(21) Appl. No.: 19/088,495

(22) Filed: Mar. 24, 2025

(51) Int. Cl. H01L 23/538; H01L 23/14; H01L 23/31; H01L 23/36; H01L 23/48; H01L 25/00; H01L 25/07

(52) U.S. Cl. CPC H10W 70/611; H10W 90/00; H10W 90/401; H10W 20/20; H10W 40/10; H10W 70/698; H10W 74/111

(57) ABSTRACT

A package includes a substrate, a first die electrically coupled to the substrate, and a second die electrically coupled to the substrate and disposed in a side-by-side arrangement with the first die. The first die includes first through-substrate vias (TSVs) that extend between a first side and a second side. The second die includes second TSVs that extend between a first side and a second side. The package includes a bridge disposed at least partially over the first die and the second die. The first TSVs, the second TSVs, and a first set of conductors that are internal to the bridge electrically interconnect the first die and the second die. The package also includes second conductors that are internal to the substrate. The second set of conductors electrically interconnects the first die and the second die.

### FIELD

Various features relate to device packages.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. Integrated device package design has evolved in an attempt to meet these various goals; however, these goals are often in conflict with one another. For example, smaller integrated device packages may be more expensive to manufacture and provide less space for routing conductive paths between dies and/or other components of the integrated device package, which can limit electrical performance. One approach to address many of these goals is to use a package-on-package (PoP) configuration; however, PoP configurations can introduce other concerns, such as heat management. Due in part to heat management concerns, designers of high-end electronic devices may prefer side-by-side configurations. However, interconnecting two high-end dies together in a side-by-side configuration on a package substrate can present challenges. For example, signals that are routed between the dies via some conductive paths can experience interference from other signals routed between the dies in nearby conductive paths. To shield these signal paths from such interference, package substrates may include additional layers to allow for sufficient spacing between signal paths, and contact pitch on the dies may be designed in view of this spacing. Increasing the number of layers in the package substrate and the contact pitch can increase the size and cost of these multi-die device packages.

### SUMMARY

Various features relate to integrated circuit devices and/or packages.

One example provides a package that includes a substrate and a first die electrically coupled to the substrate and having a first set of through-substrate vias (TSVs) that extend between a first side of the first die and a second side of the first die. The package also includes a second die electrically coupled to the substrate and disposed in a side-by-side arrangement with the first die on the substrate. The second die has a second set of TSVs that extend between a first side of the second die and a second side of the second die. The package also includes a bridge disposed at least partially over the first side of the first die and the first side of the second die. The first set of TSVs, the second set of TSVs, and a first set of conductors that are internal to the bridge electrically interconnect the first die and the second die. The package also includes a second set of conductors that are internal to the substrate. The second set of conductors electrically interconnect the first die and the second die.

Another example provides a method of fabrication that includes electrically coupling a first die to a substrate. The first die has a first set of through-substrate vias (TSVs) that extend between a first side of the first die and a second side of the first die. The method also includes electrically coupling a second die to the substrate in a side-by-side arrangement with the first die on the substrate. The second die has a second set of TSVs that extend between a first side of the second die and a second side of the second die. The method also includes coupling a bridge at least partially to the first side of the first die and to the first side of the second die. The first set of TSVs, the second set of TSVs, and a first set of conductors that are internal to the bridge electrically interconnect the first die and the second die. A second set of conductors that are internal to the substrate electrically interconnect the first die and the second die.

Optional additional aspects are described in the dependent claims.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross-sectional profile view of an example of a package that includes a device-to-device (D2D) bridge over multiple side-by-side dies with substrate interconnections between the dies.

FIG. 1B illustrates a cross-sectional profile view of a first example of a package that includes the D2D bridge over the side-by-side dies with substrate interconnections of FIG. 1A and an additional D2D bridge over the substrate.

FIG. 1C illustrates a cross-sectional profile view of a first example of a package that includes the D2D bridge over the side-by-side dies with substrate interconnections of FIG. 1A and an embedded D2D bridge within the substrate.

FIG. 1D illustrates a cross-sectional profile view of a first example of a package that includes the D2D bridge over the side-by-side dies with substrate interconnections of FIG. 1A, an additional D2D bridge over the substrate, and an embedded D2D bridge within the substrate.

FIG. 2 illustrates a cross-sectional profile view of an example of a package that includes passive device(s) and/or heat spreader(s) in addition to a D2D bridge over multiple dies with substrate interconnections.

FIG. 3 illustrates a cross-sectional profile view of an example of a package that includes a D2D bridge configured to provide heat dissipation and substrate interconnections between side-by-side dies with substrate interconnections.

FIG. 4A illustrates a first part of an exemplary sequence for fabricating an exemplary package that includes a D2D bridge over side-by-side dies with substrate interconnections.

FIG. 4B illustrates a second part of an exemplary sequence for fabricating an exemplary package that includes a D2D bridge over side-by-side dies with substrate interconnections.

FIG. 4C illustrates a third part of an exemplary sequence for fabricating an exemplary package that includes a D2D bridge over side-by-side dies with substrate interconnections.

FIG. 4D illustrates a fourth part of an exemplary sequence for fabricating an exemplary package that includes a D2D bridge over side-by-side dies with substrate interconnections.

FIG. 5 illustrates an exemplary flow diagram of a method of fabrication for a package that includes a D2D bridge over side-by-side dies with substrate interconnections.

FIG. 6 illustrates various electronic devices that may integrate an exemplary package that includes a D2D bridge over side-by-side dies with substrate interconnections described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, components and circuitry may be shown in block diagrams in order to avoid obscuring the aspects in unnecessary detail. In other instances, well-known structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

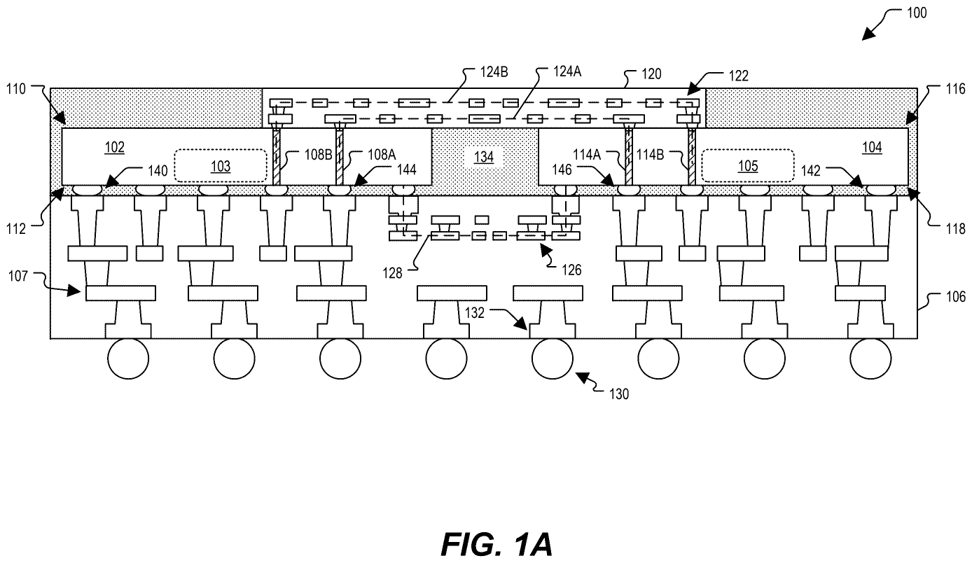

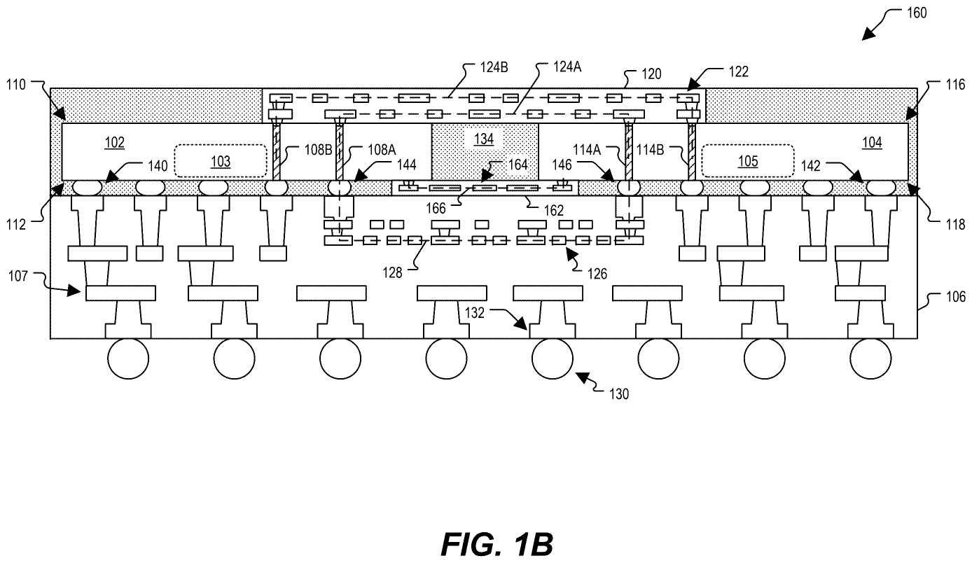

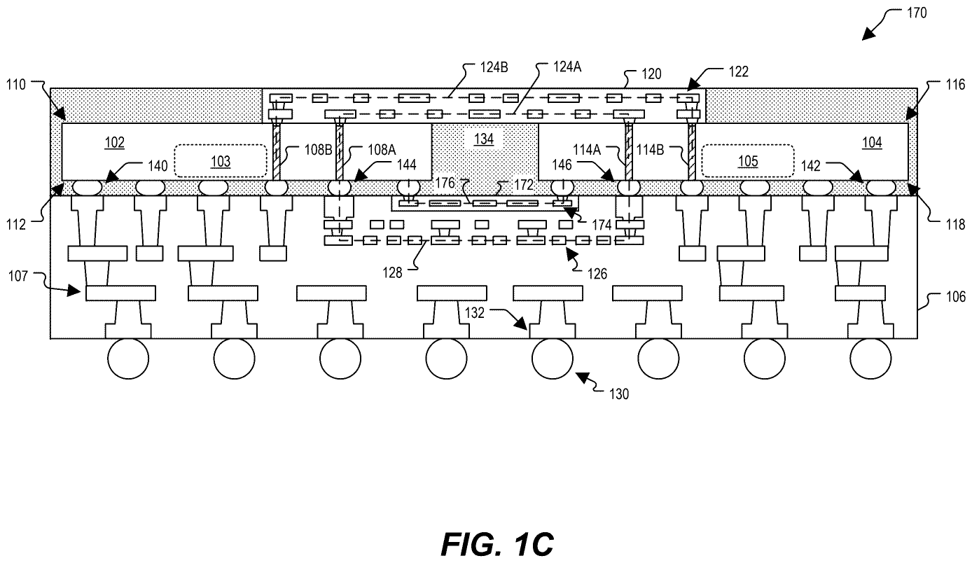

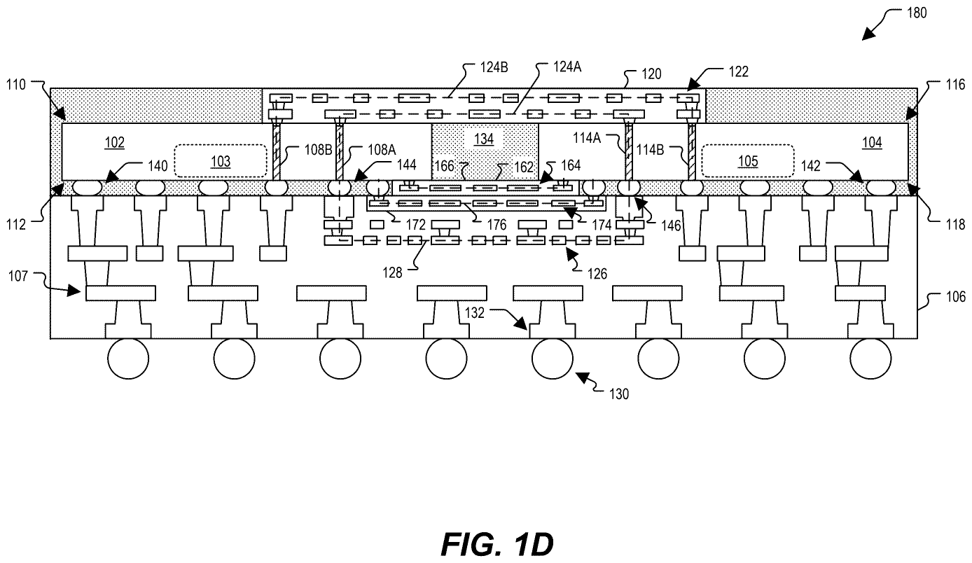

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1A, multiple signal paths are illustrated and associated with reference numbers 124A and 124B. When referring to a particular one of these signal paths, such as a signal path 124A, the distinguishing letter “A” is used. However, when referring to any arbitrary one of these signal paths or to these signal paths as a group, the reference number 124 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. As used herein, a side-by-side configuration or side-by-side arrangement refers to multiple dies or chiplets that are disposed adjacent to one another (typically in a horizontal direction) on the same substrate or interposer (or interconnected substrates or interposers) instead of being stacked vertically as a three-dimensional (3D) IC device. A 3D IC device refers to an IC device that stacks multiple layers of chips or chiplets on top of each other. Stacked die schemes and chiplet architectures are becoming more common as significant power performance area (PPA) yield enhancements are demonstrated for stacked die and chiplet architecture product lines.

Aspects of the present disclosure are directed to packages including a device-to-device (D2D) bridge over side-by-side dies with substrate interconnections. As used herein, a D2D bridge refers to a bridge or interposer that includes interconnections designed to electrically couple dies integrated within close proximity in a single package. In some circumstances, packages with side-by-side die arrangements may be preferred over package-on-package (PoP) arrangements, such as to reduce heat management concerns. However, package substrates for side-by-side dies can be expensive to fabricate. For example, a laminate package substrate may include six metal layers in order to provide power, ground, off-package connections, and adequate isolation between signal paths. The number of metal layers needed can be reduced by using redistribution layer (RDL) materials and techniques instead of or in addition to using lamination materials and techniques; however, RDL fabrication is generally much more expensive than laminate substrate manufacturing.

Particular examples disclosed herein address some or all of these concerns, by using one or more D2D bridges in combination with substrate interconnections to interconnect dies in a side-by-side arrangement within a package. For example, a particular package (e.g., a device or an integrated device package) can include a substrate, a first die electrically coupled to the substrate, and a second die electrically coupled to the substrate and disposed in a side-by-side arrangement with the first die on the substrate. In this example, the first die may have a first set of through-substrate vias (TSVs) that extend between a first side of the first die and a second side of the first die, and the second die may have a second set of TSVs that extend between a first side of the second die and a second side of the second die. The package can include a bridge disposed at least partially over the first side of the first die and the first side of the second die, and the bridge can include a first set of conductors that are internal to the bridge. The package can also include a second set of conductors that are internal to the substrate. Such a package provides electrical interconnections between the first die and the second die within both the bridge and the substrate. For example, the bridge, the first set of TSVs, the second set of TSVs, and the first set of conductors that are internal to the bridge can electrically interconnect the first die and the second die, and a second set of conductors that are internal to the substrate can also electrically interconnect the first die and the second die. Additional embodiments disclosed herein include additional bridges, such as a bridge between the dies and the substrate, a bridge embedded in the substrate, or both, that provide additional electrical interconnections between the dies that are separate from the bridge covering the dies and the substrate.

Using one or more D2D bridges in combination with substrate interconnections to electrically interconnect dies in a side-by-side arrangement reduces the layer count of a package as compared to other packages that route D2D signals through the substrate without using a bridge. Additionally, using a bridge to route signals that are more susceptible to interference in combination with routing signals that generate more interference through the substrate can provide protection from interference to the signals routed through the bridge (i.e., the signals that experience more degradation from interference). Such a package layout can reduce a layer count of the substrate as compared to packages that route all D2D signals through the substrate and also provide improved interference reduction as compared to packages that route all D2D signals through a bridge, thereby resulting in a package with reduced cost and complexity, and improved performance, as compared to other packages with side-by-side dies. Some embodiments described herein provide additional interference protection by routing sets of signals through additional bridges, such as a bridge disposed between the dies and the substrate, an embedded bridge, or both.

Additionally, or alternatively, in some embodiments, the package can include additional components that provide other benefits and do not further increase a height, and thus cost and complexity, of the package. For example, in some embodiments, the package can also include one or more passive components, such as capacitors, resistors, inductors, diodes, etc., that are disposed over portions of the first die and/or the second die that are not covered by the bridge. Additionally, or alternatively, one or more heat spreaders (or other thermal components) may be disposed similarly over the uncovered portions of the first die and/or the second die. The passive components and/or the heat spreaders may be designed to have a substantially same height as the bridge, such that including the passive components or the heat spreaders does not increase the height of the package. In this manner, the package may be configured to support one or more passive electronic components, to provide improved thermal dissipation, or both, without increasing the size of the package. In some other embodiments, the bridge can include a combination bridge and passive component or heat spreader that supports both D2D signal routing and passive electronic component(s)/improved thermal dissipation using a single component.

Further, different materials and fabrication techniques can be used for different bridges or the package substrate. To illustrate, in the example above, less expensive laminate materials and fabrication techniques can be used for the package substrate, and more expensive RDL materials and fabrication techniques can be used for the bridge. Alternatively, a different set of laminate materials may be used for the bridge, such as silicon, laminate materials, or passive interposer materials. Using different materials or layer types for the bridge and the package substrate, which optionally can be formed using different materials and/or different fabrication techniques, offers several technical advantages. For example, the different bridges and the package substrate can be redesigned or modified separately, such as due to updated constraints or use of different dies, which improves design and manufacturing flexibility. Using different bridges and the package substrate to route various signals between dies can address cost goals and package size goals at the same time. For example, consider a package in which the package substrate may be formed using lamination techniques, and a bridge may be formed using RDL techniques. In this example, the package substrate is likely to be thicker but less expensive than the bridge. However, the use of RDL techniques to form the bridge may enable the signal paths to be spaced closer together while still satisfying routing constraints, resulting in a bridge that is thinner than the package substrate and thinner than if the bridge were formed using lamination techniques. Thus, the overall dimensions of the package (including the bridge and the package substrate) are less than the overall dimensions of a package that includes a single laminate package substrate in which all the signals are routed or a single bridge in which all the signals are routed. Likewise, the combined cost of fabricating the bridge and the package substrate is less than the cost of fabricating a single RDL-based package substrate or a single RDL-based bridge.

### Exemplary Packages Including a D2D Bridge Over Side-by-Side Dies and Substrate Interconnections

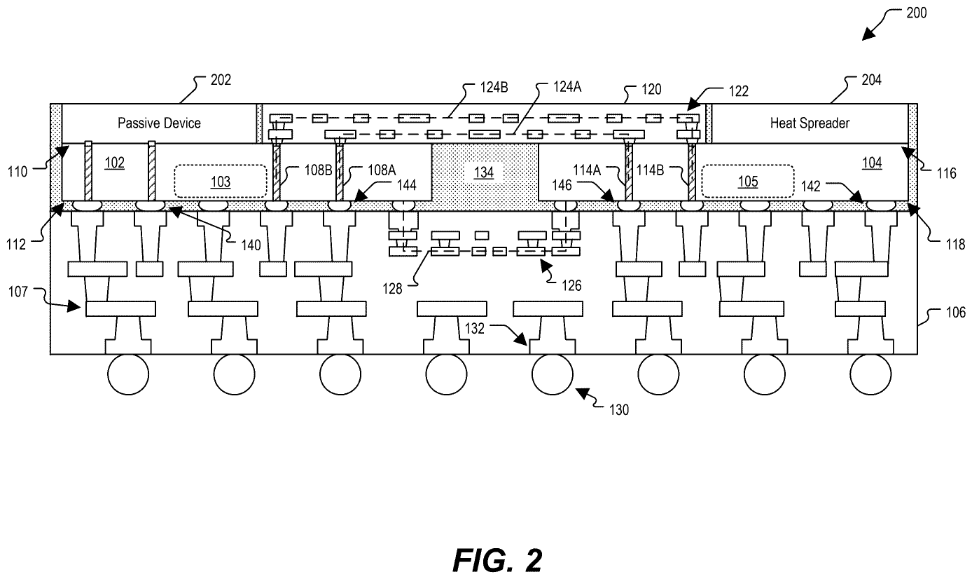

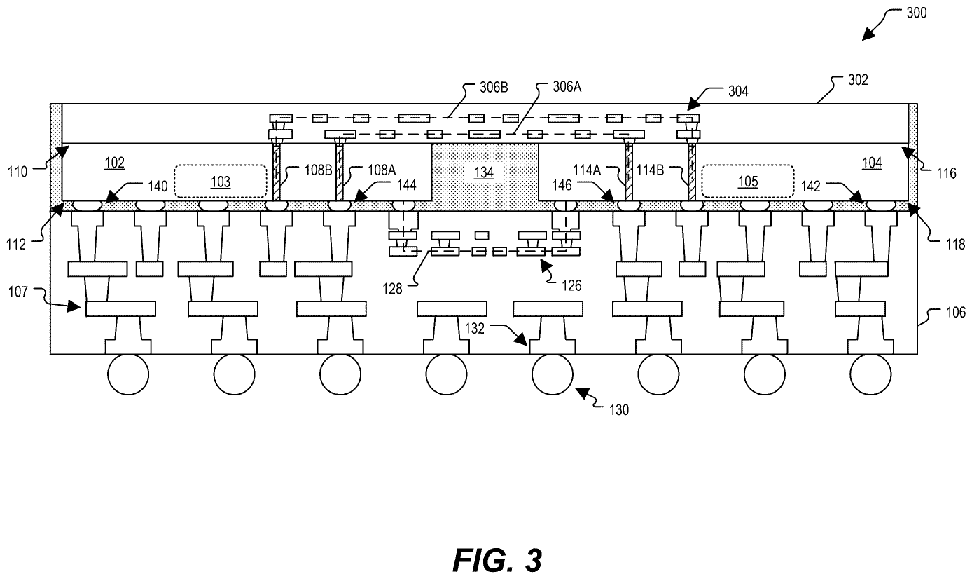

FIGS. 1A-3 illustrate various examples of packages (e.g., integrated device packages) that include D2D bridges over side-by-side dies with substrate interconnections. FIGS. 1B-1D depict packages that include one or more additional bridges in addition to the example shown in FIG. 1A, and FIGS. 2-3 depict packages that include some or all of the components of the package shown in FIG. 1A, although in other implementations, the examples shown in FIGS. 2-3 could also include the components of any of FIGS. 1B-1D. The various examples shown in FIGS. 1A-3 highlight particular non-limiting aspects of packages according to the present disclosure.

In the example shown in FIG. 1A, a package 100 includes a die 102 (e.g., a first die) and a die 104 (e.g., a second die) that are each electrically coupled to a package substrate 106. The dies 102, 104 are disposed in a side-by-side (SxS) arrangement on the package substrate 106, as shown in FIG. 1A. The package 100 also includes a bridge 120 (e.g., a D2D bridge) that is disposed over portions of the dies 102, 104 and that is electrically coupled to the dies 102, 104. The dies 102, 104 are interconnected by signal paths within the bridge 120 and signal paths within the package substrate 106, as further described herein. The package 100 also includes an encapsulant 134 that at least partially surrounds or encapsulates the die 102, the package substrate 106, the die 104, and the bridge 120. The encapsulant 134 may retain the die 102 and the die 104 in position relative to one another in a side-by-side configuration and/or resist warpage of the package 100. In some implementations, the encapsulant 134 includes or corresponds to a mold compound. Alternatively, the encapsulant 134 may be a different type of compound, such as adhesive or glue, that provides a mechanical connection between at least the die 102 and the die 104.

The package substrate 106 includes a set of metal layers 107 that are separated from one another by dielectric layers and that are patterned and interconnected to form conductors (e.g., contacts, lines, and vias). The conductors of the package substrate 106 are configured to route various signals to or from the die 102 and the die 104. For example, one of the metal layers 107 defines die contacts (e.g., contact arrays), corresponding to contacts of the die 102 and contacts of the die 104, disposed on the top (e.g., a first side) of the package substrate 106. Further, another of the metal layers 107 defines a set of contacts 132 (e.g., off package contacts) disposed on or included in the bottom (e.g., a second side) of the package substrate 106 and configured to be coupled, via interconnects 130 (e.g., solder balls or solder bumps), to another substrate such as a printed circuit board (PCB). In other examples, the contacts 132 are configured to couple, via the interconnects 130, to another electrical interconnection and/or one or more other devices (e.g., other discrete components, other packages, etc.).

One or more of the metal layers 107 are configured to route power and ground between and among respective pairs or sets of the contacts 132 and the die contacts that correspond to the dies 102, 104. For example, one or more of the metal layers 107 may support a power delivery network (PDN) associated with the die 102 or the die 104. Additionally, one or more of the metal layers 107 are configured to route at least some signals between and among respective pairs or sets of the die contacts and the contacts 132. Further, one or more of the metal layers 107 and vias or other conductive structures are patterned and configured as conductors 126 (e.g., a set of substrate conductors) that are configured to route at least some signals between die contacts corresponding to the die 102 and die contacts corresponding to the die 104.

In the example illustrated in FIG. 1A, four metal layers 107 of the package substrate 106 are illustrated; however, in other examples, the package substrate 106 can include fewer than four or more than four metal layers 107. For example, the package substrate 106 can include as many metal layers 107 as are needed to route signals, power, and ground between the die 102 and the contacts 132, to route signals, power, and ground between the die 104 and the contacts 132, and to route at least some signals between the dies 102, 104, based on the routing constraints associated with the package substrate 106. The routing constraints can depend on materials and fabrication techniques used to form the package substrate 106, the characteristics of the die 102, the characteristics of the die 104, industry or company standard design considerations, etc. To illustrate, the routing constraints may be based on line width and line spacing of conductive lines of the metal layers 107, including the conductors 126, associated with materials and fabrication techniques used to form the package substrate 106, line separation selected to maintain signal integrity for various signals routed to or from the die 102 or the die 104, a contact configuration of the die 102, a contact configuration of the die 104, etc.

The package substrate 106 or portions thereof (or layer(s) directly on top of the package substrate 106) can be formed using different materials or techniques that contribute to the thickness or count of the metal layers 107, the thickness or count of dielectric layers, or both. As one illustrative example, the package substrate 106 can be formed using lamination techniques and may include a metal-prepreg composite stack, in which the dielectric layers include fiber-reinforced polymer layers. Alternatively, the package substrate 106 can include a set of redistribution layers, in which the dielectric layers include unreinforced polymer layers. In the example in which the package substrate 106 (or a top portion thereof) includes the set of redistribution layers, the metal layers 107 are each thinner than in the example in which the package substrate 106 is formed using lamination techniques (e.g., includes one or more laminate layers), as is typical for redistribution layers as compared to laminated metal-prepreg composite stacks. Stated another way, the materials and fabrication techniques used to form the package substrate 106 can also influence other characteristics of the package substrate 106. For example, differences between the materials and fabrication techniques used to form redistribution layers as compared to laminated metal-prepreg stacks can enable the redistribution layers to have comparatively finer line width and finer pitch between lines and/or contacts, which enables higher density routing of signal paths.

Each of the dies 102, 104 can include various circuits. For example, each of the dies 102, 104 can include integrated circuitry, such as a plurality of transistors and/or other circuit elements arranged and interconnected to form logic cells, memory cells, filters, amplifiers, etc. For example, the die 102 may include circuitry 103 configured to support the operations described herein with reference to the die 102. Similarly, the die 104 may include circuitry 105 configured to support the operations described herein with reference to the die 104. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate. As non-limiting examples, the die 102, the die 104, or both, can include one or more of a power management integrated circuit (PMIC), an application processor, a modem, a radio frequency (RF) device, a passive device, a filter, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory circuit, a power management processor, and/or combinations thereof. In additional non-limiting examples, the die 102, the die 104, or both, can include one or more microcontrollers, application-specific integrated circuits (ASICs), field programmable gate arrays (FPGAs), central processing units (CPUs) having one or more processing cores, processing systems, system-on-chip (SoC), or other circuitry and logic configured to facilitate the operations of the dies 102, 104. Additionally, or alternatively, one or both of the dies 102, 104 may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof.

In some embodiments, the circuitry 103 includes or corresponds to a first application processor (e.g., first processor circuitry), and the circuitry 105 includes or corresponds to a second application processor (e.g., second processor circuitry), although either of the circuitry 103 or the circuitry 105 could instead be a SoC (e.g., processor circuitry) or a DRAM in other embodiments. In some other embodiments, the die 102 includes or corresponds to a first chiplet, the die 104 includes or corresponds to a second chiplet, and the circuitries 103, 105 may each include or correspond to respective chiplet circuitry. In the example shown in FIG. 1A, the dies 102, 104 include through-substrate vias (TSVs) to electrically couple the circuitry 103 or the circuitry 105 to one or more components coupled to sides of the dies 102, 104. For example, the die 102 includes TSVs 108 (e.g., a first set of TSVs) that extend between a first side 110 (e.g., the top) of the die 102 and a second side 112 (e.g., the bottom) of the die 102. Similarly, the die 104 includes TSVs 114 (e.g., a second set of TSVs) that extend between a first side 116 (e.g., the top) of the die 104 and a second side 118 (e.g., the bottom) of the die 104. As used herein, a via extends between two components or features (e.g., the first side and the second side of a respective die, in this example) if the via extends through an entirety of the respective die or through at least a portion of the respective die, including ending on one or both sides of the respective die. For example, one or more of the TSVs 108 may extend from the first side 110 of the die 102 (e.g., from a bridge pad included in or on the first side 110) through an entirety of the die 102 to the second side 112 of the die 102 (e.g., to an interconnect pad included in or on the second side 112). Additionally, or alternatively, one or more of the TSVs 108 may extend from the first side 110 of the die 102 to an intermediate layer of the die 102 (e.g., to couple to the circuitry 103). The TSVs 114 may similarly extend from the first side 116 of the die 104 to either the second side 118 of the die 104 or to an intermediate layer (e.g., to couple to the circuitry 105).

In addition to active circuits, one or both of the dies 102, 104 can include various passive components, such as capacitors, inductors, or resistors. Further, while each die 102, 104 is illustrated as a single monolithic device in FIG. 1A, in other embodiments, the die 102, the die 104, or both, can include or be replaced with a stacked integrated circuit device, e.g., a stack of chiplets. For example, the die 102, the die 104, or both, may include or correspond to one or more chiplets upon which other chiplets or layers may be stacked.

The dies 102, 104 are coupled to the package substrate 106 by respective interconnects (e.g., contacts, pads, bumps, microbumps, conductive pillars, or other conductive structures). For example, interconnects 140 (e.g., a first set of interconnects) may be coupled between the second side 112 of the die 102 and the package substrate 106, and interconnects 142 (e.g., a second set of interconnects) may be coupled between the second side 118 of the die 104 and the package substrate 106. The interconnects 140, 142 may include microbumps, C4 bumps, solder bumps, or other types of interconnects. In some embodiments, the interconnects 140 provide one or more power connections, one or more ground connections, or both, to the die 102 and the interconnects 142 provide one or more power connections, one or more ground connections, or both, to the die 104. In some embodiments, subsets of the interconnects 140, 142 that are included in signal paths that are internal to the bridge 120 or that are coupled to the conductors 126 may have different characteristics (e.g., size, contact pitch, etc.) than others of the interconnects 140, 142. To illustrate, the signal paths to the bridge 120 and/or the conductors 126 (e.g., die contacts) may be electrically coupled to the interconnects 140 (e.g., the subset 144 of the interconnects 140) and to the interconnects 142 (e.g., the subset 146 of the interconnects 142). Because at least some signals between the dies 102, 104 are routed through the bridge 120, fewer of the signals are routed through the package substrate 106 (e.g., to the contacts 132 or between dies by the conductors 126), and accordingly, the contact pitch associated with the interconnects 140, 142 is larger than for integrated package devices in which all of the signals between dies are routed through the package substrate. As referred to herein, a pitch associated with a set of contacts refers to a distance between two adjacent contacts measured from corresponding points of the two adjacent contacts, such as the centers of the respective contacts.

The bridge 120 is disposed at least partially over the first side 110 (e.g., the back) of the die 102 and the first side 116 (e.g., the back) of the die 104. The bridge 120 may include or be formed from a variety of materials. For example, the bridge 120 may be a silicon bridge. Alternatively, the bridge 120 may include one or more redistribution layers. Alternatively, the bridge 120 may be a laminate bridge (e.g., the bridge 120 may include one or more laminate layers of a laminate prepreg stack). Alternatively, the bridge 120 may be a passive bridge (e.g., the bridge 120 may include one or more passive interposer layers that do not include any active circuitry). Although the bridge 120 is shown in FIG. 1A as being disposed over only portions of the dies 102, 104, in some other embodiments, the bridge 120 may have a width that is substantially similar to the combined widths of the dies 102, 104 (and the space in-between the dies 102, 104), as further described herein with reference to FIG. 3.

The bridge 120 is configured to provide at least some D2D connections between the die 102 and the die 104. For example, the bridge 120 includes one or more conductors 122 that are internal to the bridge 120, such as one or more metal layers, one or more vias, other conductive structures, or a combination thereof, that are internal to the bridge 120 and that provide conductive paths between bridge contacts that are coupled to the dies 102, 104. The conductors 122 can include multiple metal layers within the bridge 120, but do not include conductors outside the bridge 120, such as metal layers, traces, or contacts on or included in the top of the bridge 120. In some examples, the conductors 122 may be formed using similar materials or techniques as the conductors 126 within the package substrate 106.

The die 102 and the die 104 are electrically interconnected by one or more signal paths through the bridge 120 and one or more signal paths through the package substrate 106. For example, signal paths 124 (e.g., a first set of signal paths) electrically interconnect the die 102 and the die 104, and the signal paths 124 include the TSVs 108, the TSVs 114, and the conductors 122 that are internal to the bridge 120 (and optionally one or more pads, contacts, and/or interconnects between the bridge 120 and the dies 102, 104). To illustrate, a signal path that electrically connects the circuitry 103 and the circuitry 105 may include a TSV 108A, one or more conductors 122A, and a TSV 114A, and another signal path that electrically connects the circuitry 103 and the circuitry 105 may include a TSV 108B, one or more conductors 122B, and a TSV 114B. Additionally, signal paths 128 (e.g., a second set of signal paths) that electrically interconnect the die 102 and the die 104 include the conductors 126 that are internal to the package substrate 106.

It should be understood that the package 100 may include additional components, other components, fewer components, or a combination thereof, to support the functionality described herein. As non-limiting examples, the package 100 may include additional IC devices, additional layers, additional dies, additional packages, additional interconnects, additional structures, other components, different components, or a combination thereof, to support the functionality and technical advantages disclosed herein.

The package 100 provides a package having side-by-side dies with reduced package size as compared to other packages that route D2D signals entirely through a package substrate or entirely through a bridge. For example, by offloading many of the D2D signal paths (e.g., the signal paths 124) to the bridge 120 instead of the package substrate 106, the number of layers in the package substrate 106 may be reduced, such as by one to three layers in some examples, as compared to other side-by-side packages. If the bridge 120 is formed using materials or techniques that enable closer lines, the overall height of the package 100 is reduced by reducing the layer count of the package substrate 106 and moving some signal paths to the bridge 120, thereby reducing cost of the package 100. Reducing the layer count can also reduce a path of a PDN to the die 102 or the die 104, which can provide the technical benefit of improved alternating current load (ACL) and direct current resistance (DCR), as well as introduction of less parasitics. Additionally, routing some D2D signals between the dies 102, 104 through the package substrate (e.g., through the signal paths 128) enables an increased pitch associated with the contacts of the bridge 120 as compared to packages that only route D2D signals through a bridge while also enabling an increased contact pitch associated with the interconnects 140, 142. Such increased contact pitches may be easier to align with TSV pitch associated with the TSVs 108, 114 as well as being less complex and less expensive to fabricate, as compared to the other packages. Additionally, using the bridge 120 to route at least some signals in combination with routing other signals through the package substrate 106 can protect each group of signals from interference caused by the other group of signals. Such a package layout can also provide improved interference reduction to other signals or connections routed through the package substrate 106 as compared to packages that route all D2D signals through a package substrate.

In the example illustrated in FIG. 1B, a package 160 includes the components of the package 100 and an additional D2D bridge over the package substrate 106. As illustrated in FIG. 1B, the package 160 includes a bridge 162 that is disposed over or above the package substrate 106 and that is coupled to the second side 112 of the die 102 and to the second side 118 of the die 104. In this example, the bridge 162 is disposed between the dies 102, 104 and the package substrate 106, and the bridge 162 is electrically coupled to the dies 102, 104 by one or more of the subset 144 of the interconnects 140 or the subset 146 of the interconnects 142, respectively (and/or one or more pads, contacts, or other type of interconnects). The bridge 162 may include any of the types of materials, and be formed using any of the types of fabrication techniques, as described with reference to the bridge 120. For example, the bridge 162 may include a silicon bridge, a redistribution layer bridge, a laminate bridge, or a passive interposer bridge.

The bridge 162 is configured to provide at least some D2D connections between the die 102 and the die 104. For example, the bridge 162 includes one or more conductors 164 that are internal to the bridge 162, such as one or more metal layers, one or more vias, other conductive structures, or a combination thereof, that are internal to the bridge 162 and that provide conductive paths between bridge contacts that are coupled to the dies 102, 104. The conductors 164 can include one or more metal layers within the bridge 162, but do not include conductors outside the bridge 162, such as metal layers, traces, or contacts included in or on the bottom of the bridge 162. In some examples, the conductors 164 may be formed using similar materials or techniques as the conductors 126 within the package substrate 106 and/or the conductors 122 within the bridge 120.

The die 102 and the die 104 are electrically interconnected by one or more signal paths through the bridge 162, in addition to the signal paths 124 within the bridge 120 and the signal paths 128 within the package substrate 106. For example, signal paths 166 (e.g., a third set of signal paths) electrically interconnect the die 102 and the die 104, and the signal paths 166 include the conductors 164 that are internal to the bridge 162 (and optionally one or more pads, contacts, the subsets 144, 146 of the interconnects 140, 142, and/or other interconnects between the bridge 162 and the dies 102, 104). By including the bridge 162 in the package 160, additional signals between the dies 102, 104 may be grouped together and routed through the signal paths 166 separately from the signals that are routed through the signal paths 124 and the signal paths 128, which may reduce interference between the various groups of signals and further improve performance of the package 160.

In the example illustrated in FIG. 1C, a package 170 includes the components of the package 100 and an additional embedded D2D bridge within the package substrate 106. As illustrated in FIG. 1C, the package 170 includes an embedded bridge 172 that is embedded within the package substrate 106 and that is coupled to the second side 112 of the die 102 and to the second side 118 of the die 104. In this example, the embedded bridge 172 is disposed between the dies 102, 104 and the conductors 126 within the package substrate 106, and the embedded bridge 172 is electrically coupled to the dies 102, 104 by one or more of the subset 144 of the interconnects 140 or the subset 146 of the interconnects 142, respectively (and/or one or more pads, contacts, or other types of interconnects). To illustrate, a third set of interconnects (e.g., one or more of the subset 144 of the interconnects 140) may be coupled between the die 102 and the embedded bridge 172, and a fourth set of interconnects (e.g., one or more of the subset 146 of the interconnects 142) may be coupled between the die 104 and the embedded bridge 172. In other examples, the embedded bridge 172 may be embedded below the conductors 126 and coupled to the subset 144 of the interconnects 140 and the subset 146 of the interconnects 142 by one or more vias (and optionally one or more of the metal layers 107). The embedded bridge 172 may include any of the types of materials, and be formed using any of the types of fabrication techniques, as described with reference to the bridge 120. For example, the embedded bridge 172 may include a silicon bridge, a redistribution layer bridge, a laminate bridge, or a passive interposer bridge.

The embedded bridge 172 is configured to provide at least some D2D connections between the die 102 and the die 104. For example, the embedded bridge 172 includes one or more conductors 174 that are internal to the embedded bridge 172, such as one or more metal layers, one or more vias, other conductive structures, or a combination thereof, that are internal to the embedded bridge 172 and that provide conductive paths between bridge contacts that are coupled to the dies 102, 104. The conductors 174 can include one or more metal layers within the embedded bridge 172, but do not include conductors outside the embedded bridge 172, such as metal layers, traces, or contacts on or included in the bottom of the embedded bridge 172. In some examples, the conductors 174 may be formed using similar materials or techniques as the conductors 126 within the package substrate 106 and/or the conductors 122 within the bridge 120.

The die 102 and the die 104 are electrically interconnected by one or more signal paths through the embedded bridge 172, in addition to the signal paths 124 within the bridge 120 and the signal paths 128 within the package substrate 106. For example, signal paths 176 (e.g., a fourth set of signal paths) electrically interconnect the die 102 and the die 104, and the signal paths 176 include the conductors 174 that are internal to the embedded bridge 172 (and optionally one or more pads, contacts, and/or the subsets 144, 146 of the interconnects 140, 142, between the embedded bridge 172 and the dies 102, 104). By including the embedded bridge 172 in the package 170, additional signals between the dies 102, 104 may be grouped together and routed through the signal paths 176 separately from the signals that are routed through the signal paths 124 and the signal paths 128, which may reduce interference between the various groups of signals and further improve performance of the package 170.

In the example illustrated in FIG. 1D, a package 180 includes the components of the package 100, the bridge 162 of FIG. 1B, and the embedded bridge 172 of FIG. 1C. In this example, signals between the die 102 and the die 104 may be grouped into one of four groups, and the groups of signals may be routed through the signal paths 124 within the bridge 120, the signal paths 128 within the package substrate 106, the signal paths 166 within the bridge 162, and the signal paths 176 within the embedded bridge 172, respectively.

The packages 160, 170, and 180 of FIGS. 1B, 1C, and 1D provide technical benefits as compared to packages that only route D2D signals through a package substrate or a bridge. For example, routing some D2D signals between the dies 102, 104 through the bridge 162, the embedded bridge 172, or both, in addition to the bridge 120 and the package substrate 106, enables an increased pitch associated with the contacts on or included in the bridge 120, the bridge 162, the embedded bridge 172, or a combination thereof, by reducing the number of signals routed through each of the bridges. Such increased contact pitches may be easier to align with TSV pitch associated with the TSVs 108, 114 as well as being less complex and less expensive to fabricate, as compared to the other packages. Additionally, using the bridge 162, the embedded bridge 172, or both, to route at least some signals in combination with routing other signals through the package substrate 106 and the bridge 120 can protect each group of signals from interference caused by the other group of signals. Such a package layout can also provide improved interference reduction to other signals or connections routed through the package substrate 106 as compared to packages that route all D2D signals through a package substrate.

FIG. 2 illustrates an example of a package 200 that includes many of the same features as the package 100 of FIG. 1A. For example, the package 200 includes the die 102, the die 104, and the package substrate 106 that includes the conductors 126. The package 200 also includes the bridge 120 that includes the conductors 122. Although not shown, in other implementations, the package 200 may include the features of the package 160 of FIG. 1B, the package 170 of FIG. 1C, or the package 180 of FIG. 1D, such as the bridge 162, the embedded bridge 172, or both.

The package 200 also includes a passive device 202 coupled to the first side 110 of the die 102 or the first side 116 of the die 104, a heat spreader 204 coupled to the first side 110 of the die 102 or the first side 116 of the die 104, or a combination thereof. The passive device 202 may include a capacitor, a resistor, a filter, or another type of passive electronic component. As a particular example, the passive device 202 includes a silicon capacitor that supports high performance and/or high speed logic dies such as a network signal processor (NSP), a CPU, or a modem, or that supports rails configured to enable translation between communication protocols, such as a processor-based protocol to a physical (PHY) protocol associated with a DRAM or other component. The heat spreader 204 can include, for example, a bulk silicon block, a metal block (e.g., a copper block), or a block of another high-thermal conductivity material. The heat spreader 204 may be disposed over the back side of a die that is associated with high heat generation or high power output. In some embodiments, the heat spreader 204 is coupled to the first side 116 of the die 104 using a dielectric layer, which can function as an adhesive, a thermal interface material, or both. In the example shown in FIG. 2, the encapsulant 134 at least partially surrounds the die 102, the die 104, the bridge 120, and the passive device 202 and/or the heat spreader 204.

Although the passive device 202 is illustrated as being disposed over the back of the die 102 and the heat spreader 204 is illustrated as being disposed over the back of the die 104 in FIG. 2, in other implementations, the location of the passive device 202 and the heat spreader 204 may be swapped. Although referred to as a single passive device 202 and a single heat spreader 204, the passive device 202 may include one or multiple passive devices, and the heat spreader 204 may include one or multiple heat spreaders. In other implementations, the package 200 includes multiple passive devices 202 disposed over both the dies 102, 104 and the heat spreader 204 is omitted. In other implementations, the package 200 includes multiple heat spreaders 204 disposed over both the dies 102, 104 and the passive device 202 is omitted.

In some embodiments, a height of the passive device 202 and/or a height of the heat spreader 204 is less than or equal to a height of the bridge 120. As such, the passive device 202 and/or the heat spreader 204 may be included in the integrated package without increasing the overall height of the package 200. As such, a technical benefit of the package 200 is the capability to provide additional functionality without increased cost and complexity of fabrication. For example, because the package 200 includes the passive device 202 and/or the heat spreader 204, the package 200 may be configured to support one or more passive electronic components, to provide improved thermal dissipation, or both, without increasing the size of the package 200.

FIG. 3 illustrates an example of a package 300 that includes many of the same features as the package 100 of FIG. 1A. For example, the package 300 includes the die 102, the die 104, and the package substrate 106 that includes the conductors 126. Although not shown, in other implementations, the package 300 may include the features of the package 160 of FIG. 1B, the package 170 of FIG. 1C, or the package 180 of FIG. 1D, such as the bridge 162, the embedded bridge 172, or a combination thereof.

Unlike the packages 100, 160, 170, 180, and 200 of FIGS. 1A-2, the package 300 includes a hybrid bridge structure 302 (e.g., instead of the bridge 120). The hybrid bridge structure 302 is coupled to the dies 102, 104 (e.g., to the TSVs 108, 114) similarly as described with reference to the bridge 120. The hybrid bridge structure 302 includes conductors 304 that are internal to the hybrid bridge structure 302, similar to the conductors 122 of the bridge 120. Signal paths 306 (e.g., a first set of signal paths) electrically interconnect the dies 102, 104 and include the TSVs 108, the TSVs 114, and the conductors 304, similar to as described above with reference to the signal paths 124. However, unlike the bridge 120, the hybrid bridge structure 302 substantially covers the die 102 and the die 104. For example, a width of the hybrid bridge structure 302 may be substantially equal to a combination of the widths of the dies 102, 104, and the intervening space between the dies. In some implementations, the hybrid bridge structure 302 is configured to provide heat dissipation to the die 102 and the die 104. For example, in addition to including the conductors 304, portions of the hybrid bridge structure 302 may include silicon, a metal, or another thermally conductive material that operates as a heat spreader. Additionally, or alternatively, the hybrid bridge structure 302 may provide the functionality of one or more passive electronic components. For example, metal layers, vias, dielectric layers, and the like, of the hybrid bridge structure 302 may be patterned or configured to form a capacitor or another passive electronic component in addition to the conductors 304. As such, the package 300 may provide some of the additional functionality described with reference to the package 200 of FIG. 2 using a single component (e.g., the hybrid bridge structure 302), which may further reduce cost and complexity of the package 300 while also enabling the additional functionality.

In a particular implementation, each of the packages 100, 160, 170, 180, 200, and 300 includes a first substrate (e.g., the package substrate 106), a first die electrically coupled to the substrate (e.g., the die 102), and a second die (e.g., the die 104) electrically coupled to the substrate and disposed in a side-by-side arrangement with the first die on the substrate. The first die has a first set of TSVs (e.g., the TSVs 108) that extend between a first side (e.g., the first side 110) of the first die and a second side (e.g., the second side 112) of the first die. The second die has a second set of TSVs (e.g., the TSVs 114) that extend between a first side (e.g., the first side 116) of the second die and a second side (e.g., the second side 118) of the second die. Each of the packages 100, 160, 170, 180, 200, 300 also includes a bridge (e.g., the bridge 120 or the hybrid bridge structure 302) disposed at least partially over the first side of the first die and the first side of the second die. The first set of TSVs, the second set of TSVs, and a first set of conductors (e.g., the conductors 122 or the conductors 304) that are internal to the bridge electrically interconnect the first die and the second die. Each of the packages 100, 160, 170, 180, 200, 300 also includes a second set of conductors (e.g., the conductors 126) that are internal to the substrate. The second set of conductors electrically interconnects the first die and the second die.

### Exemplary Sequence for Fabricating a Package Including a D2D Bridge Over Side-By-Side Dies with Substrate Interconnections

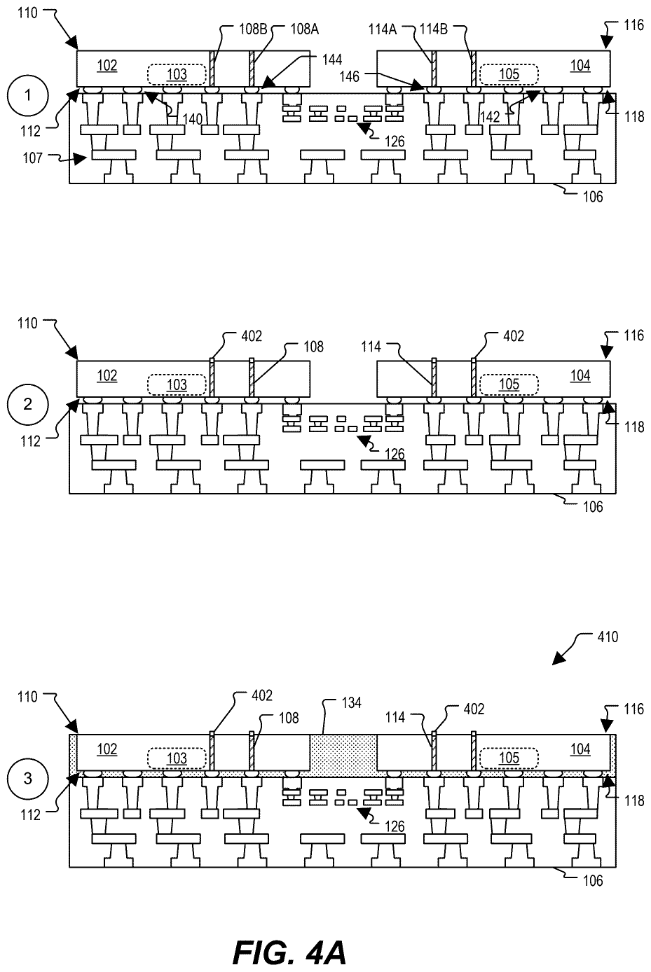

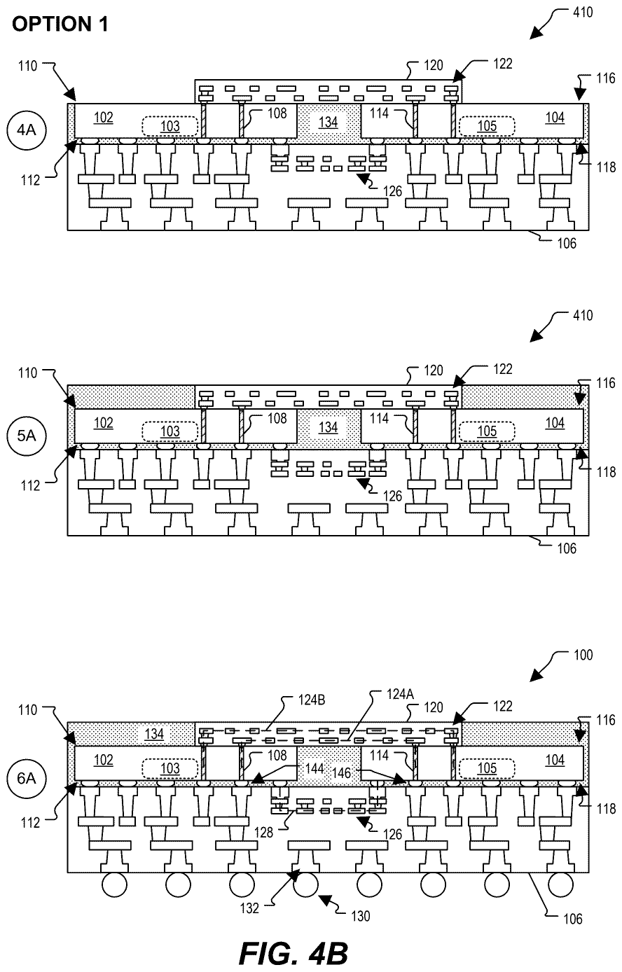

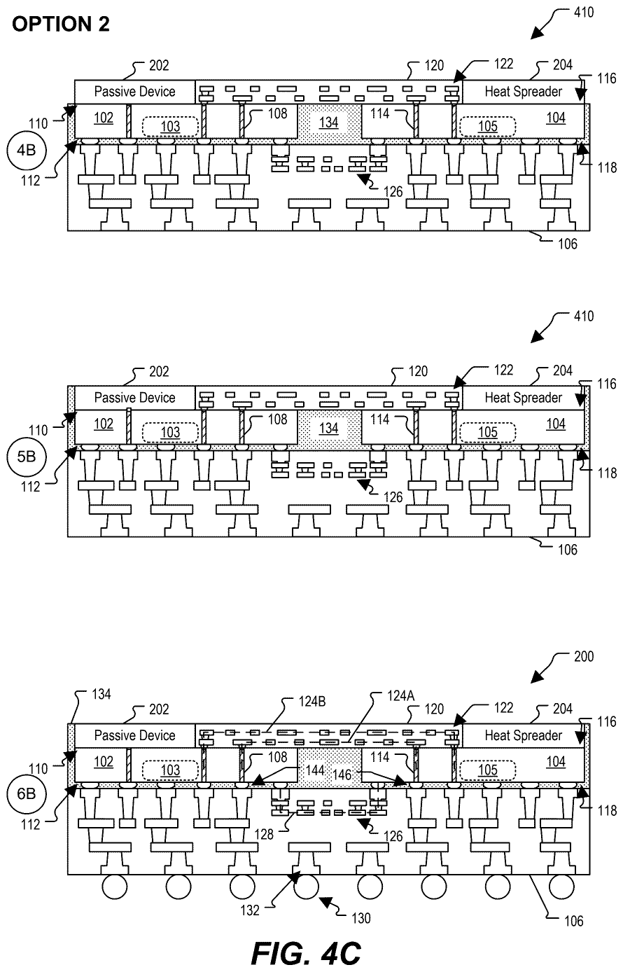

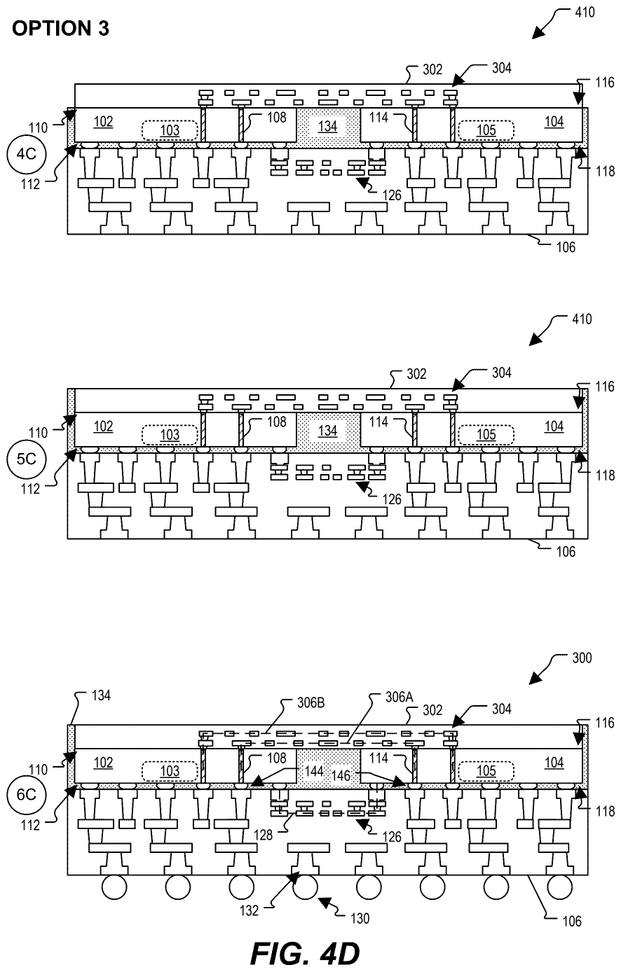

In some implementations, fabricating a package that includes two or more dies in a side-by-side arrangement, a bridge, and substrate interconnections (e.g., any of the packages 100, 200, or 300 of FIGS. 1A, 2, and 3) includes multiple operations. FIGS. 4A, 4B, 4C, and 4D, together, illustrate various stages of an exemplary sequence for fabricating or providing a package or device that includes multiple dies, a substrate, and additional structures (e.g., a bridge that includes a first set of conductors internal to the bridge and a second set of conductors internal to the substrate). In some implementations, the sequence of FIGS. 4A-D may be used to provide (e.g., during fabrication of) one or more of the package 100 of FIG. 1A, the package 200 of FIG. 2, or the package 300 of FIG. 3.

It should be noted that the sequence of FIGS. 4A-D may combine one or more stages in order to simplify and/or clarify the sequence for providing or fabricating a package. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers or circled numbers and letters in combination) in FIGS. 4A-D. Each of the various stages of the sequence illustrated in FIGS. 4A-D shows a single package being formed. In other implementations, multiple packages may be formed concurrently, e.g., using strip level or panel level operations.

Stage 1 of FIG. 4A illustrates a state after the die 102 (e.g., a first die) and the die 104 (e.g., a second die) are coupled to the package substrate 106. For example, as part of Stage 1, one or more of the interconnects 140 on or included in the second side 112 of the die 102 may be coupled to pads on or included in the package substrate 106 that are formed from the metal layers 107. Similarly, one or more of the interconnects 142 on or included in the second side 118 of the die 104 may be coupled to pads on or included in the package substrate 106 that are formed from the metal layers 107. The die 104 is coupled in a side-by-side arrangement with the die 102 on the package substrate 106.

The die 102 may include the TSVs 108 that are to be electrically coupled to the TSVs 114 of the die 104 during a later Stage. Additionally, one or more of the subset 144 of the interconnects 140 and one or more of the subset 146 of the interconnects 142 may be coupled to the conductors 126 that are disposed within the package substrate 106. The conductors 126 may be configured to route at least some signals between the dies 102, 104. The dies 102, 104 may be attached (e.g., electrically coupled) to the package substrate 106 using flip-chip die attachment techniques, such as solder reflow or thermo-compression bonding, or using surface mount technology (SMT) attachment techniques.

Stage 2 illustrates a state after forming one or more TSV pads 402 over the dies 102, 104. For example, as part of Stage 2, a metal (e.g., copper) can be deposited (e.g., plated) on or over the first side 110 of the die 102 and the first side 116 of the die 104 at locations that correspond to the TSVs 108 and the TSVs 114, respectively.

Stage 3 illustrates a state after application of the encapsulant 134 to form an assembly 410. For example, as part of Stage 3, overmolding operations may be used to apply the encapsulant 134 and backgrinding operations may be performed to planarize a surface of the encapsulant 134 and expose the TSV pads 402. After Stage 3, the encapsulant 134 at least partially surrounds (e.g., encapsulates) the package substrate 106 and the dies 102, 104.

FIGS. 4B-D each illustrate respective Options that include operations that follow after the operations described with reference to Stage 3, which include Option 1 depicted in FIG. 4B, Option 2 depicted in FIG. 4C, and Option 3 depicted in FIG. 4D. Option 1 illustrates aspects of a sequence for fabrication for a package that includes a bridge and does not include passive devices and heat spreaders. For example, Stage 4A of FIG. 4B illustrates a state after the bridge 120 is coupled to the first side 110 of the die 102 and the first side 116 of the die 104. For example, as part of Stage 4A, the bridge 120 (e.g., contacts, pads, etc., of the bridge 120) may be electrically coupled to the TSV pads 402 on or over the first side 110 of the die 102 and the first side 116 of the die 104. In the example illustrated in FIG. 4B, the bridge 120 is disposed over a portion of the die 102, a portion of the die 104, and a portion of the encapsulant 134.

Stage 5A illustrates a state after additional application of the encapsulant 134 to the assembly 410. For example, as part of Stage 5A, overmolding operations may be used to apply more of the encapsulant 134 and backgrinding operations may be performed to planarize a surface of the encapsulant 134 to be substantially planar with respect to the top of the bridge 120. After Stage 5A, the encapsulant 134 at least partially surrounds (e.g., encapsulates) the package substrate 106, the dies 102, 104, and the bridge 120.

Stage 6A illustrates a state after the interconnects 130 are coupled to the contacts 132 of the package substrate 106 to form the package 100. For example, as part of Stage 6A, solder balls or BGA elements (e.g., the interconnects 130) may be electrically coupled to the contacts 132 on or included in the bottom of the package substrate 106. Formation of the package 100 is complete after Stage 6A of FIG. 4B. As shown in FIG. 4B, the package 100 includes the signal paths 124 (e.g., a first set of signal paths) that electrically interconnect the die 102 and the die 104 and that include the TSVs 108, the TSVs 114, and the conductors 122 that are internal to the bridge 120. Additionally, the package 100 includes the signal paths 128 (e.g., a second set of signal paths) that electrically interconnect the die 102 and the die 104 and that include the conductors 126 that are internal to the package substrate 106.

Option 2 of FIG. 4C illustrates aspects of a sequence for fabrication in which the resultant package includes one or more passive devices, one or more heat spreaders, or a combination thereof. It is noted that, in option 2, the die 102 may include more TSVs 108 than shown in FIGS. 4A and 4B. In such aspects, Stage 4B of FIG. 4C illustrates a state after the bridge 120, the passive device 202, and the heat spreader 204 are coupled to the die 102 and/or the die 104. For example, as part of Stage 4B, the bridge 120 (e.g., contacts, pads, etc., of the bridge 120) may be electrically coupled to the TSV pads 402 on or over the first side 110 of the die 102 and the first side 116 of the die 104. Additionally, the passive device 202 may be coupled to one or more of the TSV pads 402 on or over the first side 110 of the die 102, and the heat spreader 204 may be coupled to the first side 116 of the die 104. The passive device 202 may include a capacitor, a resister, a filter, or another type of passive electronic component. The heat spreader 204 can include, for example, a bulk silicon block, a metal block (e.g., a copper block), or a block of another high-thermal conductivity material. A height of the passive device 202 and a height of the heat spreader 204 may be less than or equal to a height of the bridge 120.

In the example illustrated in FIG. 4C, the bridge 120 is disposed over a portion of the die 102, a portion of the die 104, and a portion of the encapsulant 134, and the passive device 202 is coupled to the die 102 and the heat spreader 204 is coupled to the die 104. In other examples, the heat spreader 204 may be coupled to the die 102 and the passive device 202 may be coupled to the die 104. Alternatively, multiple passive devices 202 may be coupled to the dies 102, 104 and the heat spreader 204 may be omitted. Alternatively, multiple heat spreaders 204 may be coupled to the dies 102, 104 and the passive device 202 may be omitted.

Stage 5B illustrates a state after additional application of the encapsulant 134 to the assembly 410. For example, as part of Stage 5B, overmolding operations may be used to apply more of the encapsulant 134 and backgrinding operations may be performed to planarize a surface of the encapsulant 134 to be substantially planar with respect to the top of the bridge 120 (and the tops of the passive device 202 and the heat spreader 204). After Stage 5B, the encapsulant 134 at least partially surrounds (e.g., encapsulates) the package substrate 106, the dies 102, 104, the bridge 120, the passive device 202, and the heat spreader 204.

Stage 6B illustrates a state after the interconnects 130 are coupled to the contacts 132 of the package substrate 106 to form the package 200. For example, as part of Stage 6B, solder balls or BGA elements (e.g., the interconnects 130) may be electrically coupled to the contacts 132 on or included in the bottom of the package substrate 106. Formation of the package 200 is complete after Stage 6B of FIG. 4C. As shown in FIG. 4C, the package 200 includes the signal paths 124 (e.g., a first set of signal paths) that electrically interconnect the die 102 and the die 104 and that include the TSVs 108, the TSVs 114, and the conductors 122 that are internal to the bridge 120. Additionally, the package 200 includes the signal paths 128 (e.g., a second set of signal paths) that electrically interconnect the die 102 and the die 104 and that include the conductors 126 that are internal to the package substrate 106.

Option 3 of FIG. 4D illustrates aspects of a sequence for fabrication in which the bridge 120 of FIG. 4A is replaced with the hybrid bridge structure 302 (e.g., a combination bridge and passive electronic component or a combination bridge and heat spreader). For example, Stage 4C of FIG. 4D illustrates a state after the hybrid bridge structure 302 is coupled to the first side 110 of the die 102 and the first side 116 of the die 104. For example, as part of Stage 4C, the hybrid bridge structure 302 (e.g., contacts, pads, etc., of the hybrid bridge structure 302) may be electrically coupled to the TSV pads 402 on or over the first side 110 of the die 102 and the first side 116 of the die 104.

Unlike the bridge 120 illustrated in Stage 4A of FIG. 4B, the hybrid bridge structure 302 substantially covers the dies 102, 104 once the hybrid bridge structure 302 is coupled to the first side 110 of the die 102 and to the first side 116 of the die 104. Although shown as covering an entirety of the die 102 and the die 104 in FIG. 4D, in other examples, the hybrid bridge structure 302 may not cover an entirety of the upper surface (e.g., the first side 110) of the die 102, an entirety of the upper surface (e.g., the first side 116) of the die 104, or both, but substantial portions of the upper surfaces of the dies 102, 104 are covered by the hybrid bridge structure 302. The hybrid bridge structure 302 includes the conductors 304 that are similar to the conductors 122 of the bridge 120. In some implementations, the hybrid bridge structure 302 is configured to provide heat dissipation to the die 102 and the die 104. For example, in addition to including the conductors 304, portions of the hybrid bridge structure 302 may include silicon, a metal, or another thermally conductive material that operates as a heat spreader. Additionally, or alternatively, the hybrid bridge structure 302 may provide the functionality of one or more passive electronic components. For example, metal layers, vias, dielectric layers, and the like, of the hybrid bridge structure 302 may be patterned or configured to form a capacitor or another passive electronic component in addition to the conductors 304.

Stage 5C illustrates a state after additional application of the encapsulant 134 to the assembly 410. For example, as part of Stage 5C, overmolding operations may be used to apply more of the encapsulant 134 and backgrinding operations may be performed to planarize a surface of the encapsulant 134 to be substantially planar with respect to the top of the hybrid bridge structure 302. After Stage 5C, the encapsulant 134 at least partially surrounds (e.g., encapsulates) the package substrate 106, the dies 102, 104, and the hybrid bridge structure 302.

Stage 6C illustrates a state after the interconnects 130 are coupled to the contacts 132 of the package substrate 106 to form the package 300. For example, as part of Stage 6C, solder balls or BGA elements (e.g., the interconnects 130) may be electrically coupled to the contacts 132 on or included in the bottom of the package substrate 106. Formation of the package 300 is complete after Stage 6C of FIG. 4D. As shown in FIG. 4D, the package 300 includes the signal paths 306 (e.g., a first set of signal paths) that electrically interconnect the die 102 and the die 104 and that include the TSVs 108, the TSVs 114, and the conductors 304 that are internal to the hybrid bridge structure 302. Additionally, the package 300 includes the signal paths 128 (e.g., a second set of signal paths) that electrically interconnect the die 102 and the die 104 and that include the conductors 126 that are internal to the package substrate 106.

Although not shown in FIGS. 4A-D, in some other embodiments, the bridge 120, the bridge 162, the embedded bridge 172, or a combination thereof, may, in addition or in alternative to the connections to the TSVs 108, 114, connect to other electrical contacts of the dies 102, 104 not shown in FIGS. 4A-D. For example, those electrical contacts may electrically connect to a circuit of the respective die or a layer of the respective die, in particular to a redistribution layer.

In some implementations, the sequences of FIGS. 4A-D may include additional operations. For example, the bridge 162 may be coupled to the package substrate 106 prior to, or concurrently with, the coupling of the die 102 and the die 104 to the package substrate 106 described with reference to Stage 1. In such an example, the dies 102, 104 may be coupled to the bridge 162 to form the signal paths 166 (e.g., one or more additional signal paths) that interconnect the dies 102, 104, as described with reference to FIG. 1B. As another example, the embedded bridge 172 may be embedded within the package substrate 106 prior to the coupling of the die 102 and the die 104 to the package substrate 106 described with reference to Stage 1. In such an example, the dies 102, 104 may be coupled to the embedded bridge 172 to form the signal paths 176 (e.g., one or more additional signal paths) that interconnect the dies 102, 104, as described with reference to FIG. 1C. As another example, the bridge 162 may be coupled to the package substrate 106 that already includes the embedded bridge 172 such that each of the bridge 162 and the embedded bridge 172 provide respective additional signal paths that interconnect the dies 102, 104, as described with reference to FIG. 1D.

### Exemplary Flow Diagram of a Method for Fabricating a Package Including a D2D Bridge Over Side-By-Side Dies with Substrate Interconnections

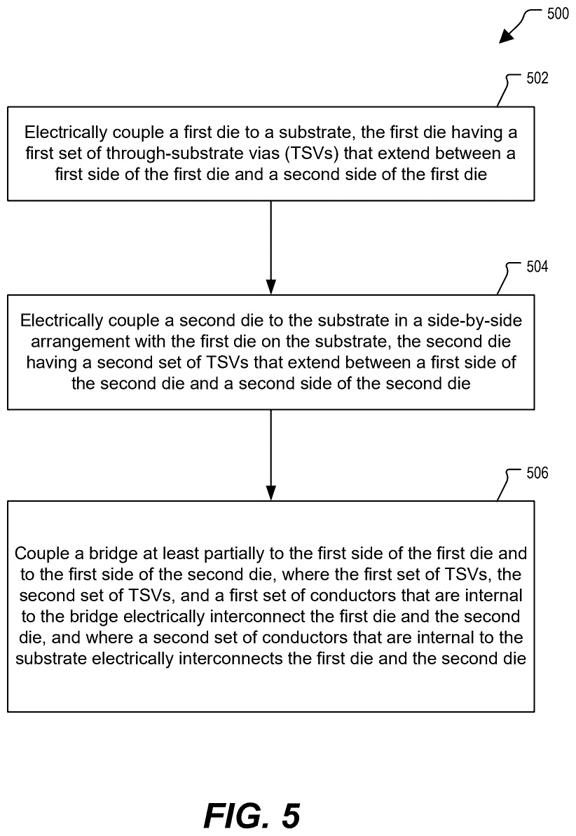

In some implementations, fabricating a device package including a D2D bridge over side-by-side dies with substrate interconnections includes several processes. FIG. 5 illustrates an exemplary flow diagram of a method 500 of fabricating an illustrative package that includes a D2D bridge over side-by-side dies with substrate interconnects. In a particular aspect, one or more operations of the method 500 are performed by one or more processors of a fabrication system. In some implementations, operations of the method 500 may be stored as instructions by a non-transitory computer-readable storage medium, and the instructions may be executable by at least one processor to cause the at least one processor to perform operations of the method 500. In some implementations, the method 500 of FIG. 5 may be used to provide or fabricate any of the packages 100, 160, 170, 180, 200, or 300.

It should be noted that the method 500 of FIG. 5 may combine one or more processes in order to simplify and/or clarify the method for providing or fabricating an integrated circuit device. In some implementations, the order of the processes may be changed or modified.

The method 500 includes electrically coupling a first die to a substrate, at block 502. For example, Stage 1 of FIG. 4A illustrates and describes examples of electrically coupling the die 102 to the package substrate 106. The first die of the method 500 can include the die 102 of FIGS. 1A-4D, and the substrate can include the package substrate 106 of FIGS. 1A-4D. The first die has a first set of TSVs that extend between a first side of the first die and a second side of the first die. For example, the first set of TSVs may include or correspond to the TSVs 108 of FIGS. 1A-4D. The first die may include first processor circuitry or a DRAM, in some implementations.

The method 500 includes electrically coupling a second die to the substrate in a side-by-side arrangement with the first die on the substrate, at block 504. For example, Stage 1 of FIG. 4A illustrates and describes examples of electrically coupling the die 104 to the package substrate 106 in a side-by-side arrangement with the die 102. The second die of the method 500 can include the die 104 of FIGS. 1A-4D. The second die has a second set of TSVs that extend between a first side of the second die and a second side of the second die. For example, the second set of TSVs may include or correspond to the TSVs 114 of FIGS. 1A-4D. The second die may include processor circuitry (e.g., second processor circuitry), in some implementations.

The method 500 includes coupling a bridge at least partially to the first side of the first die and to the first side of the second die, at block 506. For example, Stages 5A and 5B of FIGS. 4B and 4C, respectively, illustrate and describe examples of coupling the bridge 120 to the first side 110 of the die 102 and to the first side 116 of the die 104, and Stage 5C of FIG. 4D illustrates and describes examples of coupling the hybrid bridge structure 302 to the first side 110 of the die 102 and to the first side 116 of the die 104. The bridge of the method 500 can include the bridge 120 of FIGS. 1A-2, 4B, and 4C, or the hybrid bridge structure 302 of FIGS. 3 and 4D. The first set of TSVs, the second set of TSVs, and a first set of conductors that are internal to the bridge electrically interconnect the first die and the second die. For example, the first set of conductors of the method 500 may include or correspond to the conductors 122 of FIGS. 1A-2, 4B, and 4C or the conductors 304 of FIGS. 3 and 4D, and in combination with the TSVs 108 and the TSVs 114, may electrically interconnect the dies 102, 104. A second set of conductors that are internal to the substrate electrically interconnects the first die and the second die. For example, the second set of conductors of the method 500 may include or correspond to the conductors 126 of FIGS. 1A-4D. In embodiments in which the bridge of the method 500 includes the hybrid bridge structure 302, the bridge substantially covers the first die and the second die and the bridge is configured to provide heat dissipation to the first die and the second die.

In some embodiments, the method 500 also includes, prior to the coupling the bridge at least partially to the first side of the first die and to the first side of the second die, depositing an encapsulant on the first die, the second die, and the substrate. For example, Stage 3 of FIG. 4A illustrates and describes examples of depositing the encapsulant 134 on the die 102, the die 104, and the package substrate 106. In such embodiments, the method 500 also includes, after the coupling the bridge at least partially to the first side of the first die and to the first side of the second die, depositing the encapsulant over the bridge. For example, Stages 5A and 5B of FIGS. 4B and 4C, respectively, illustrate and describe examples of depositing the encapsulant 134 on the bridge 120, and Stage 5C of FIG. 4D illustrates and describes examples of depositing the encapsulant 134 on the hybrid bridge structure 302. The encapsulant of the method 500 can include the encapsulant 134 of FIGS. 1A-4D. After the final depositing operation, the encapsulant at least partially surrounds the first die, the second die, and the bridge (e.g., the bridge 120 or the hybrid bridge structure 302).

In some embodiments, the method 500 also includes coupling one or more passive devices to the first side of the first die or the first side of the second die. For example, Stage 4B of FIG. 4C illustrates and describes examples of coupling the passive device 202 to the first side 110 of the die 102. The one or more passive devices of the method 500 can include the passive device 202 of FIGS. 2 and 4C.

In some embodiments, the method 500 also includes coupling a heat spreader to the first side of the first die or the first side of the second die. For example, Stage 4B of FIG. 4C illustrates and describes examples of coupling the heat spreader 204 to the first side 116 of the die 104. The heat spreader of the method 500 can include the heat spreader 204 of FIGS. 2 and 4C.

### Exemplary Electronic Devices

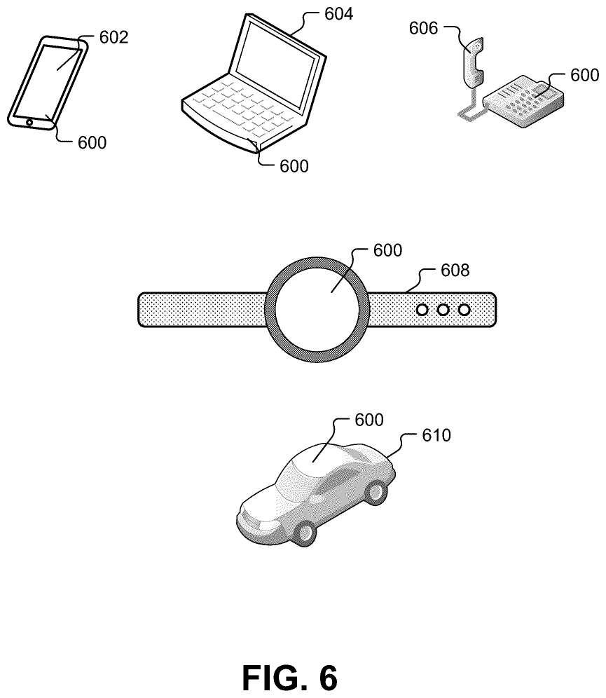

FIG. 6 illustrates various electronic devices that may include or be integrated with any of the packages 100, 160, 170, 180, 200, 300 (that includes a D2D bridge over side-by-side dies with substrate interconnections) of any of FIGS. 1A-3, 4B, 4C, or 4D. For example, a mobile phone device 602, a laptop computer device 604, a fixed location terminal device 606, a wearable device 608, or a vehicle 610 (e.g., an automobile or an aerial device) may include a device 600. The device 600 can include, for example, any of the packages 100, 160, 170, 180, 200, 300 described herein. The devices 602, 604, 606 and 608 and the vehicle 610 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-6 may be rearranged and/or combined into a single component, process, feature or function or embodied in several components, processes, or functions. Additional elements, components, processes, and/or functions may also be added without departing from the disclosure. It should also be noted FIGS. 1A-6 and its corresponding description in the present disclosure is not limited to dies and/or ICs. In some implementations, FIGS. 1A-6 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the terms “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. A UBM layer may include a thin film metal layer formed between an IC or metal pillars and solder bumps, such as in a flip chip package. In some implementations, a through-substrate via (TSV) may include or correspond to one or more types of vias depending on the material through which the TSV is formed. For example, a TSV in silicon may include or correspond to a through-silicon via, a TSV in mold compound may include or correspond to a through-mold via (TMV), and a TSV in glass may include or correspond to a through-glass via (TGV), as non-limiting examples. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a package includes: a substrate; a first die electrically coupled to the substrate and having a first set of through-substrate vias (TSVs) that extend between a first side of the first die and a second side of the first die; a second die electrically coupled to the substrate and disposed in a side-by-side arrangement with the first die on the substrate, the second die having a second set of TSVs that extend between a first side of the second die and a second side of the second die; a bridge disposed at least partially over the first side of the first die and the first side of the second die, wherein the first set of TSVs, the second set of TSVs, and a first set of conductors that are internal to the bridge electrically interconnect the first die and the second die; and a second set of conductors that are internal to the substrate, wherein the second set of conductors electrically interconnects the first die and the second die.

Example 2 includes the package of Example 1, where: the first die includes first circuitry; the second die includes second circuitry; the first set of TSVs, the second set of TSVs, and the first set of conductors electrically interconnect the first circuitry and the second circuitry; and the second set of conductors electrically interconnect the first circuitry and the second circuitry.

Example 3 includes the package of Example 1 or Example 2 and further includes an encapsulant that at least partially surrounds the first die, the second die, and the bridge.

Example 4 includes the package of any of Examples 1 to 3 and further includes one or more passive devices coupled to the first side of the first die or the first side of the second die.

Example 5 includes the package of any of Examples 1 to 4 and further includes a heat spreader coupled to the first side of the first die or the first side of the second die.

Example 6 includes the package of any of Examples 1 to 5 and further includes: a first set of interconnects coupled between the second side of the first die and the substrate, wherein the first set of interconnects provide one or more power connections, one or more ground connections, or both, to the first die; and a second set of interconnects coupled between the second side of the second die and the substrate, wherein the second set of interconnects provide one or more power connections, one or more ground connections, or both, to the second die.

Example 7 includes the package of any of Examples 1 to 6, where: the first die corresponds to a first chiplet; and the second die corresponds to a second chiplet.

Example 8 includes the package of any of Examples 1 to 7, and further includes a second bridge disposed over the substrate and coupled to the second side of the first die and the second side of the second die, wherein the second bridge is configured to electrically interconnect the first die and the second die through one or more conductors that are internal to the second bridge.

Example 9 includes the package of any of Examples 1 to 8, and further includes: a third bridge embedded within the substrate; a third set of interconnects coupled between the second side of the first die and the third bridge; and a fourth set of interconnects coupled between the second side of the second die and the third bridge, wherein the third bridge, the third set of interconnects, and the fourth set of interconnects are configured to electrically interconnect the first die and the second die through one or more conductors that are internal to the third bridge.

Example 10 includes the package of any of Examples 1 to 9, where the bridge comprises silicon.

Example 11 includes the package of any of Examples 1 to 9, where the bridge comprises one or more redistribution layers.

Example 12 includes the package of any of Examples 1 to 9, where the bridge comprises one or more laminate layers.

Example 13 includes the package of any of Examples 1 to 9, where the bridge comprises one or more passive interposer layers.

Example 14 includes the package of any of Examples 1 to 13, where the substrate, the first die, the second die, the bridge, and the second set of conductors are integrated within a mobile device, a hand-held personal communication system (PCS) unit, a portable data unit, a global positioning system (GPS) enabled device, a navigation device, a set top box, a music player, a video player, an entertainment unit, a fixed location data unit, a communications device, a smartphone, a tablet computer, a computer, a wearable device, an Internet of things (IoT) device, a server, a router, a vehicle, or a combination thereof.

According to Example 15 a method of fabrication includes: electrically coupling a first die to a substrate, the first die having a first set of through-substrate vias (TSVs) that extend between a first side of the first die and a second side of the first die; electrically coupling a second die to the substrate in a side-by-side arrangement with the first die on the substrate, the second die having a second set of TSVs that extend between a first side of the second die and a second side of the second die; and coupling a bridge at least partially to the first side of the first die and to the first side of the second die, wherein the first set of TSVs, the second set of TSVs, and a first set of conductors that are internal to the bridge electrically interconnect the first die and the second die, and wherein a second set of conductors that are internal to the substrate electrically interconnects the first die and the second die.

Example 16 includes the method of Example 15, and further includes: prior to the coupling the bridge at least partially to the first side of the first die and to the first side of the second die, depositing an encapsulant on the first die, the second die, and the substrate; and, after the coupling the bridge at least partially to the first side of the first die and to the first side of the second die, depositing the encapsulant over the bridge, wherein the encapsulant at least partially surrounds the first die, the second die, and the bridge.

Example 17 includes the method of Example 15 or Example 16 and further includes coupling one or more passive devices to the first side of the first die or the first side of the second die.

Example 18 includes the method of any of Examples 15 to 17 and further includes coupling a heat spreader to the first side of the first die or the first side of the second die.

Example 19 includes the method of any of Examples 15 to 18, where: the bridge substantially covers the first die and the second die; and the bridge is configured to provide heat dissipation to the first die and the second die.

Example 20 includes the method of any of Examples 14 to 19, where: the first die includes first processor circuitry and the second die includes second processor circuitry; or the first die includes a dynamic random-access memory (DRAM) and the second die includes processor circuitry.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package comprising:
a substrate;
a first die electrically coupled to the substrate and having a first set of through-substrate vias (TSVs) that extend between a first side of the first die and a second side of the first die;
a second die electrically coupled to the substrate and disposed in a side-by-side arrangement with the first die on the substrate, the second die having a second set of TSVs that extend between a first side of the second die and a second side of the second die;
a bridge at least partially over the first die and the second die, wherein the first set of TSVs, the second set of TSVs, and a first set of conductors that are internal to the bridge electrically interconnect the first die and the second die; and
a second set of conductors that are internal to the substrate, wherein the second set of conductors electrically interconnects the first die and the second die.

2. The package of claim 1, wherein:
the first die includes first circuitry;
the second die includes second circuitry;
the first set of TSVs, the second set of TSVs, and the first set of conductors electrically interconnect the first circuitry and the second circuitry; and
the second set of conductors electrically interconnect the first circuitry and the second circuitry.

3. The package of claim 1, further comprising:
an encapsulant that at least partially surrounds the first die, the second die, and the bridge.

4. The package of claim 1, further comprising:
one or more passive devices coupled to the first side of the first die or the first side of the second die.

5. The package of claim 1, further comprising:
a heat spreader coupled to the first side of the first die or the first side of the second die.

6. The package of claim 1, further comprising:
a first set of interconnects coupled between the second side of the first die and the substrate, wherein the first set of interconnects provide one or more power connections, one or more ground connections, or both, to the first die; and
a second set of interconnects coupled between the second side of the second die and the substrate, wherein the second set of interconnects provide one or more power connections, one or more ground connections, or both, to the second die.

7. The package of claim 1, wherein:
the first die corresponds to a first chiplet; and
the second die corresponds to a second chiplet.

8. The package of claim 1, further comprising:
a second bridge disposed over the substrate and coupled to the second side of the first die and the second side of the second die, wherein the second bridge is configured to electrically interconnect the first die and the second die through one or more conductors that are internal to the second bridge.

9. The package of claim 1, further comprising:
a third bridge embedded within the substrate;
a third set of interconnects coupled between the second side of the first die and the third bridge; and
a fourth set of interconnects coupled between the second side of the second die and the third bridge, wherein the third bridge, the third set of interconnects, and the fourth set of interconnects are configured to electrically interconnect the first die and the second die through one or more conductors that are internal to the third bridge.

10. The package of claim 1, wherein the bridge comprises silicon.

11. The package of claim 1, wherein the bridge comprises one or more redistribution layers.

12. The package of claim 1, wherein the bridge comprises one or more laminate layers.

13. The package of claim 1, wherein the bridge comprises one or more passive interposer layers.

14. The package of claim 1, wherein the substrate, the first die, the second die, the bridge, and the second set of conductors are integrated within a mobile device, a hand-held personal communication system (PCS) unit, a portable data unit, a global positioning system (GPS) enabled device, a navigation device, a set top box, a music player, a video player, an entertainment unit, a fixed location data unit, a communications device, a smartphone, a tablet computer, a computer, a wearable device, an Internet of things (IoT) device, a server, a router, a vehicle, or a combination thereof.

15. A method of fabrication, the method comprising:
electrically coupling a first die to a substrate, the first die having a first set of through-substrate vias (TSVs) that extend between a first side of the first die and a second side of the first die;
electrically coupling a second die to the substrate in a side-by-side arrangement with the first die on the substrate, the second die having a second set of TSVs that extend between a first side of the second die and a second side of the second die; and
coupling a bridge at least partially to the first side of the first die and to the first side of the second die,
wherein the first set of TSVs, the second set of TSVs, and a first set of conductors that are internal to the bridge electrically interconnect the first die and the second die, and
wherein a second set of conductors that are internal to the substrate electrically interconnects the first die and the second die.

16. The method of claim 15, further comprising:
prior to the coupling the bridge at least partially to the first side of the first die and to the first side of the second die, depositing an encapsulant over the first die, the second die, and the substrate; and
after the coupling the bridge at least partially to the first side of the first die and to the first side of the second die, depositing the encapsulant over the bridge, wherein the encapsulant at least partially surrounds the first die, the second die, and the bridge.

17. The method of claim 15, further comprising:
coupling one or more passive devices to the first side of the first die or the first side of the second die.

18. The method of claim 15, further comprising:
coupling a heat spreader to the first side of the first die or the first side of the second die.

19. The method of claim 15, wherein:
the bridge substantially covers the first die and the second die; and
the bridge is configured to provide heat dissipation to the first die and the second die.

20. The method of claim 15, wherein:
the first die includes first processor circuitry and the second die includes second processor circuitry; or
the first die includes a dynamic random-access memory (DRAM) and the second die includes processor circuitry.
